(19) United States
(12) Patent Application Publication
(10) Pub. No.: US 2010/0014691 A1
(43) Pub. Date: Jan. 21, 2010

(54) AUTONOMOUS VOLUME CONTROL

(76) Inventors: Braon Moseley, Round Rock, TX (US); Mark T. Stiner, LaFollette, TN (US)

Correspondence Address: David E. Wilder, 707 East Clinton Ave., Huntsville, AL, 35801, US

(21) Appl. No.: 12/173,811

(22) Filed: Jul. 15, 2008

(51) Int. Cl. H03G 3/20

(52) U.S. Cl. 381/107; 381/86

(57) ABSTRACT

An autonomous volume control device is described which has detectors for measuring tilt and acceleration in one or more axes. The amount of tilt and acceleration is used as an indication of the amount and type of vehicle activity, thus being used also to control the volume of the vehicle's audio system. The described volume control device requires no wiring or connections to any vehicle subsystem and the device may be mounted to the vehicle without any particular orientation being required.

### FIELD OF THE INVENTION

The present invention pertains to the field of automatic volume control for sound systems used on vehicles. More specifically, the present invention is in the field of automatically controlling the volume of a sound system in a vehicle to overcome ambient noise caused by vehicle activity and maneuvers or to adjust the volume to different levels desired during different activity events.

### BACKGROUND OF THE DISCLOSURE

When using a sound system in a vehicle, for example a radio or CD player in an automobile or a boat, a listener normally experiences difficulty in setting the sound system volume to a level that is acceptable under varying vehicle conditions. In an automobile or motorcycle, road and engine noise increases as vehicle speed increases and as road conditions get rougher. Similarly, ambient noise in a water sports vehicle increases as the vehicle's level of activity and maneuvering increases. The vehicle passenger often desires a higher volume output from the sound system to overcome the increasing noise. Also, the vehicle passenger may desire different volume levels during different activity events. The different volume levels for different events is not just to overcome ambient noise. For example, in a water sports vehicle the driver and passengers may want loud music to encourage the party atmosphere while pulling a skier at high speed but low volume to allow easy communication when slowly circling back to pick up a fallen skier.

The prior art offers numerous examples of methods and devices to automatically control the volume of a sound system in response to vehicle speed. In U.S. Pat. No. 3,233,178 to Byles (1966), a radio with speed compensated volume control is described. Additional prior art U.S. Pat. No. 4,558,460 to Tanaka et al. (1985), U.S. Pat. No. 4,933,987 to Parks (1990), U.S. Pat. No. 5,027,432 to Skala et al. (1991), U.S. Pat. No. 5,034,984 to Bose (1991), and U.S. Pat. No. 5,677,960 to Unno et al. (1997) all teach adjusting the volume in response to a speed indication or a closely related signal such as the engine's RPM or a signal from the vehicle's alternator. U.S. Pat. No. 4,944,018 to Bose et al. (1990) mentions using engine-sensing, speed-sensing, and other noise-representative inputs. U.S. Pat. No. 5,483,692 to Person et al. (1996) refers to the use of speed, RPM, transmission gear, throttle, and the output of the acceleration control module. U.S. Patent Application Pub. No. 2004/0042624 to Henderson et al. (2004) describes the use of the status of doors and windows to predict desirable volume levels. U.S. Patent Application Pub. No. 2004/0258254 to Mollon teaches the use of an output signal from the suspension system to determine road conditions and thus predict noise levels.

Other prior art attempts to measure ambient noise and adjust the sound system volume when ambient noise varies. U.S. Pat. No. 6,584,201 to Konstantinou et al. (2003) describes an apparatus which uses microphones to measure the ambient noise and the sound system volume, compares the two, and adjusts the sound system volume in response to the comparison. U.S. Patent Application Pub. No. 2004/0151328 to Hasegawa et al. and U.S. Patent Application Pub. No. 2004/0042624 to Henderson et al. also refer to detecting or measuring ambient noise for use in determining desirable volume levels.

### SUMMARY OF THE DISCLOSURE

The present invention is an autonomous volume control device which is intended to be used on a vehicle such that the present invention adjusts the volume control of an audio system to compensate for the varying levels of noise caused by vehicle movements and maneuvers or to adjust the volume to different desired levels for different activity events. In the present invention, the amount of tilt and acceleration along one or more axes is detected. The amount of tilt and acceleration is used to detect the vehicle's maneuvers. Once the present invention has detected the vehicle's maneuvers, the invention adjusts the volume level of the audio system.

### BRIEF DESCRIPTION OF THE DRAWINGS

FIG. 1 shows one embodiment of the present invention being used to detect vehicle activity and adjusting the volume of a sound system.

FIG. 2 shows a flow diagram of the process used by one embodiment of the present invention to establish and maintain an accurate assessment of the vehicle's baseline activity level.

FIG. 3 shows a diagram which illustrates the nature of the decision thresholds typically used in the present invention.

FIG. 4 shows a flow diagram of the process used by one embodiment of the present invention to gather information used to decide the appropriate action to take.

### DETAILED DESCRIPTION

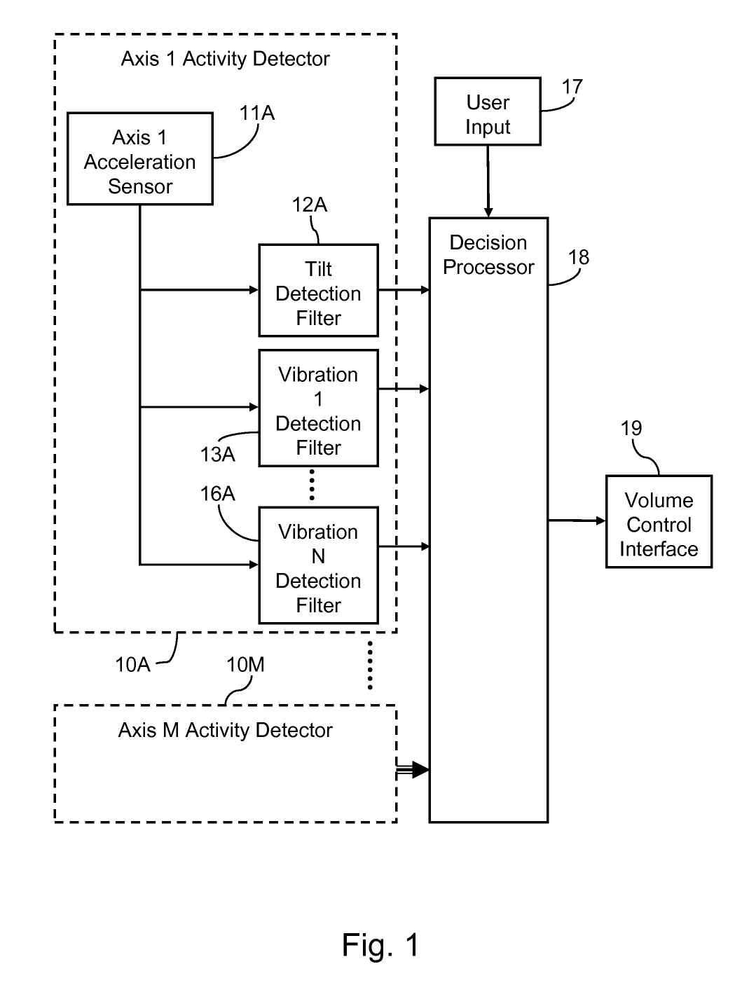

As shown in FIG. 1, one embodiment of the present invention contains a Decision Processor 18 connected to one or more Activity Detectors 10A 10M, a User Input 17, and a Volume Control Interface 19. Axis 1 Activity Detector 10A contains Axis 1 Acceleration Sensor 11A, which is connected to one or more filters 12A 13A 16A. Tilt Detection Filter 12A takes the output of Axis 1 Acceleration Sensor 11A and detects the presence of acceleration variations with frequency characteristics which may indicate the vehicle is tilting. Additional vibration detection filters 13A 16A may be used to detect the presence of vibrations with frequency characteristics which may indicate other vehicle activities of interest. Additional activity detectors, including the shown Axis M Activity Detector 10M, may be used. A convention of placing three acceleration sensors orthogonal to each other is often used, though other arrangements are feasible. The various activity detectors need not be identical. The type of acceleration sensor and the types of filters in each activity detector may be optimized for the particular orientation of the acceleration sensor or the type of vehicle on which the present invention is placed. User Input 17 is connected to the Decision Processor 18 for the purpose of allowing the user to input volume adjustment commands to adjust the behavior of the present invention. Decision Processor 18, after processing its various inputs, outputs a control signal to the vehicle's sound system via the Volume Control Interface 19.

The Tilt Detection Filter 12A and the various vibration detection filters 13A 16A process the output of the Axis 1 Acceleration Sensor 11A by frequency and amplitude content to detect a number of conditions. This information is useful to the Decision Processor 18 in determining the past, current, and future state of the autonomous volume control device. The various filters described may be implemented any number of ways, for example using analog circuits, digital filter circuits, or software implemented filters in a microprocessor or computer.

Very slowly time varying acceleration (up to about 1 hertz) due to gravity is useful in detecting the tilt state of the present invention. Tilt information is useful to the Decision Processor 18 in detecting what state the autonomous volume control device is in, or what event may be occurring, what event may have just occurred, or what event may be about to occur. For example, in a water sports context a watercraft at rest will exhibit a static tilt. Once the watercraft develops a velocity, whether it is turning or not, the bow of the watercraft may rise. Maneuvers of the vehicle can cause the direction and amount of tilt to change.

Slowly time varying acceleration (from about 1 hertz to about 5 hertz) is useful in detecting acceleration forces which tend to be of larger magnitude and of longer duration. For example, in a water sports context slowly time varying acceleration may be the result of passengers moving about the watercraft or waves acting on the watercraft while the watercraft is otherwise not in motion.

Medium time varying acceleration (from about 6 hertz to about 100 hertz) is useful in detecting acceleration forces which tend to be of medium magnitude and medium duration. For example, in a water sports context medium time varying acceleration may be the result of the watercraft traversing waves at a medium to fast (about 10-50 miles per hour) velocity.

Fast time varying acceleration (from about 101 hertz to about 3000 hertz) is useful in detecting acceleration forces which tend to be of a small magnitude and of short duration. For example, in a water sports context fast time varying acceleration may be the result of the engine operating in the watercraft. Engine idle acceleration (from about 500 hertz to about 1000 Hertz) can be useful in characterizing the lower limit of engine operation as well as the watercraft operator's intent of operation including the current mode of operation. Engine cruise or full throttle acceleration (from about 1001 hertz to about 3000 Hertz) can be useful in characterizing the upper limit of engine operation.

Very fast and extremely fast acceleration (from about 3001 hertz to about 20,000 hertz) is useful in detecting acceleration forces that tend to be of extremely small amplitude and of extremely short duration. For example, in a water sports context very fast and extremely fast acceleration may be the result of highly amplified audio output equipment resident on the watercraft. Characterization of the amplitude of these signals over time can help detect the presence or absence of small, medium, and highly amplified audio output.

The combination of an acceleration sensor and filter is only one type of tilt detector. There are various other types of tilt detectors (also known as tilt sensors) that are known. Some such other types are electrolytic tilt detectors, magnetic tilt detectors, and capacitive tilt detectors. Any effective tilt detector may be used to create an embodiment of the present invention. The combination of an acceleration sensor and filter for use as a tilt detector is simply one embodiment of the present invention.

The Decision Processor 18 receives sensor information and user commands, determines the past, current, and future state of the present invention, and transmits information to the Volume Control Interface 19 in order affect the volume of the vehicle's sound system. The nature of the Volume Control Interface 19 depends on the specifics of the particular sound system. The Decision Processor 18 may be implemented any number of ways, for example using a microprocessor, using a computer, digital circuits, or using analog components such as comparators.

For one embodiment of this invention, the Volume Control Interface 19 is an infrared remote control interface. Such a remote control interface allows this embodiment to be a self-contained unit which can be installed in a vehicle easily. In other embodiments of this invention, the Volume Control Interface 19 may be a wired control interface or a system bus.

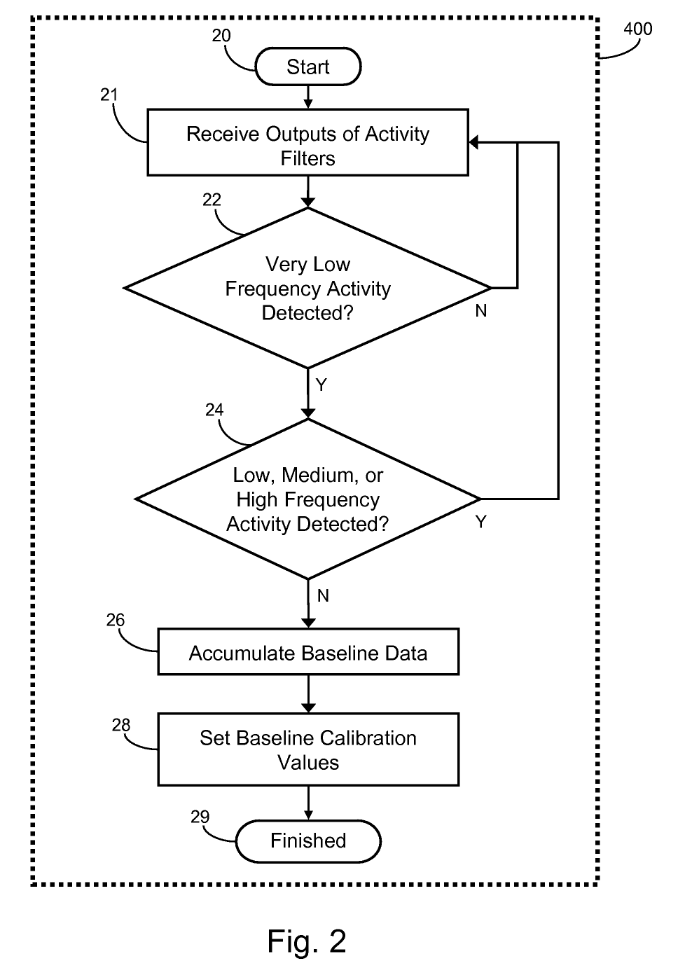

FIG. 2 shows a flow diagram of a baseline calibration algorithm 400 which is used to determine the direction of the acceleration due to gravity with respect to the autonomous volume control device. The autonomous volume control device may be mounted in any variety of orientations, therefore a method must exist for arbitrary orientation of the autonomous volume control device not to hamper the autonomous volume control device's ability to properly detect and interpret state changes. The calibration algorithm starts at step 20. The Decision Processor 18 receives the outputs of the activity detectors 10A 10M in step 21. If very low frequency activity is detected at step 22 and higher frequency activity is not detected at step 24, the current activity levels are accumulated into the baseline data at step 26. The baseline data is used in step 28 to set various orientation parameters in the memory within the Decision Processor 18. The algorithm finishes at step 29. The baseline calibration algorithm may be implemented any number of ways, for example using a microprocessor, a computer, digital circuits, or analog circuits.

The very slowly time varying acceleration information is normally collected over a relatively long period of time. The average of activity values sampled is used as the mathematical representation of the direction of acceleration due to gravity. This average is updated continuously. With a typical three axis sensors present, each orthogonal to one another, a basic mathematical vector transform can represent the static acceleration due to gravity. For the processing of the tilt state of the present invention, this baseline vector is subtracted from the instantaneous very slow time varying acceleration inputs from the acceleration sensor, the difference represents the degree to how far out of baseline the instantaneous measurement was. For example, in a water sports context the autonomous volume control device can baseline a level indication when the watercraft is simply floating in the water. If the autonomous volume control device detects any low to high frequency events, the autonomous volume control device will not accumulate baseline data for this period of time because vehicle activity may be present. This accumulation of baseline data over time is effective in orienting the autonomous volume control device, and allowing the tilt and activity event detection algorithms to function properly.

More than one state of tilt is identifiable, each corresponding to a separate activity event. For example, in a water sports context, the watercraft may exhibit axial tilt from bow to stern of about zero degrees while the rider is getting set up, and the driver and passengers are moving about the watercraft. An axial tilt from bow to stern of from about 5 degrees to about 10 degrees may represent a slow velocity, used when approaching a rider who has recently fallen. An axial tilt from bow to stern of more than about 15 degrees may represent forward motion of the watercraft suitable for identifying this event as a wake surfing scenario. An axial tilt from bow to stern of more than about 10 degrees may represent forward motion of the watercraft suitable for identifying this event as a wake boarding scenario.

Bow to stern tilt may also be combined with port to starboard tilt. For example, in a water sports context, port to starboard tilt of greater than about 10 degrees may represent a sharp, slow velocity turn suitable for identifying this event as a driver circling to pick up a fallen rider.

Rapid acceleration along the bow to stern axis may represent a substantial increase in velocity of the autonomous volume control device. For example, in a water sports context this situation may correspond to the driver increasing throttle in order to get a rider up out of the water.

Rapid deceleration along the bow to stern axis may represent a substantial decrease in velocity of the autonomous volume control device. For example, in a water sports context this situation may correspond to the rider having fallen, and the driver turning around to pick up the rider. This situation is also likely paired with steep tilt indication along the port to starboard axis, representing a tight turn.

The instantaneous tilt indication, while sampled quickly enough and filtered adequately, may still mislead the Decision Processor 18 as to the nature of the current activity event. For this reason, the Decision Processor 18 retains in the state logic, the state of past events, in order to vote on the current event. In the case when the Decision Processor 18 has received some indication as to the state of the event which would logically indicate a command to actuate the Output Control block, the Decision Processor 18 will not command the Output Control block without the vote count exceeding a threshold designed to limit the False Positive state. In the case when the Decision Processor 18 can not be sure about the state of the autonomous volume control device, User Input 17 may be used to bump the decision vote past the threshold for Volume Control Interface 19 activation.

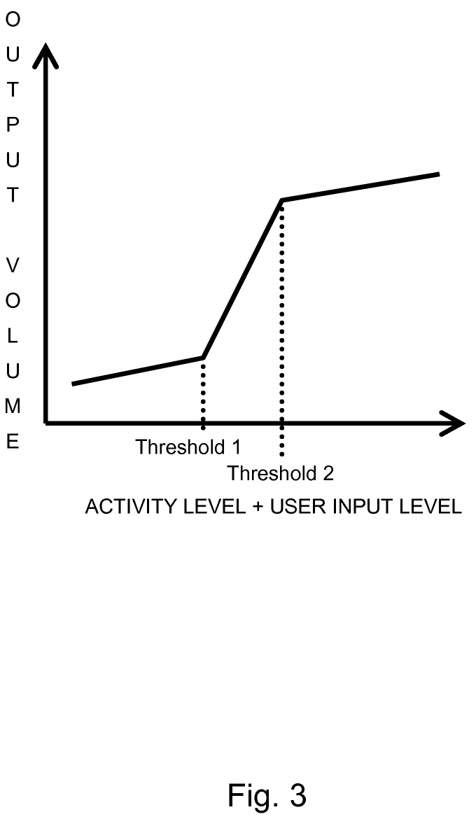

FIG. 3 shows a diagram which illustrates the nature of the decision thresholds typically used in the present invention. For activity levels below Threshold 1, a small increase in activity levels causes a small increase in sound system volume. For activity levels between Threshold 1 and Threshold 2, a small increase in activity levels causes a larger increase in sound system volume. Above Threshold 2, a small increase in activity levels again causes a small increase in sound system volume. The User Input 17 allows the user to affect these threshold points. FIG. 3 represents one example of a volume control profile that is useful. Other profiles are useful in various applications.

For example, in a water sports context the driver may exercise the controls on the watercraft in such a way as to tend to trigger action from the Decision Processor 18 logic. The autonomous volume control device is designed to limit false positive indications, so in some cases the autonomous volume control device may not drive the output level up to the level as desired by the driver, or passengers. In this case, an increase in the desired output response as indicated by User Input 17 can deliver a significant increase in vote counts to the Decision Processor 18 logic, pushing it past the threshold, and causing the autonomous volume control device to adjust the volume.

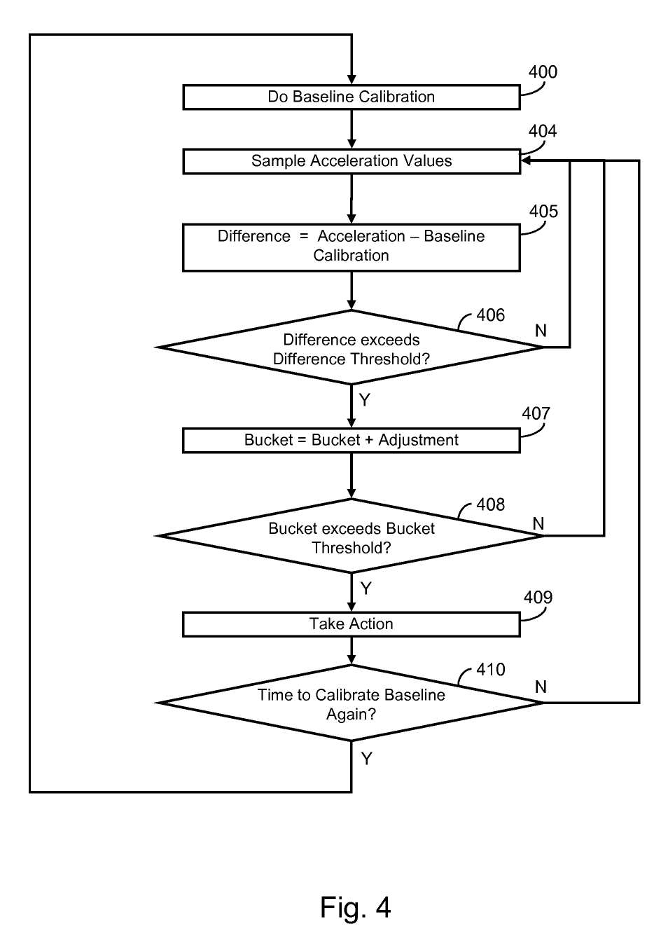

FIG. 4 shows the process used in one embodiment of the invention to gather information for making decisions about the appropriate action to take. In block 400 the baseline calibration algorithm is performed, as detailed in FIG. 2. Block 400 is followed by block 404, where the level of acceleration for one or more axes is sampled and block 405 where the sampled values are compared to the baseline calibrated value to produce a difference value. In decision block 406, this difference is compared to a difference threshold. If the difference does not exceed the difference threshold, the process loops back to block 404 to sample the level of acceleration again. If the difference does exceed the difference threshold, the process continues on with block 407 where a bucket value is adjusted up or down to reflect the level and direction of acceleration previously sampled in block 404. This bucket value is then compared to a bucket threshold in decision block 408. If the bucket value does not exceed the bucket threshold, the process loops back to block 404 to sample the level of acceleration again. If the bucket value does exceed the bucket threshold, the process continues with block 409 where the bucket value is used to decide how much to adjust the volume. After block 409, the process continues with decision block 410. Decision block 410 either directs the process back to block 404 to sample the acceleration levels again or back to block 400 to check whether to update the baseline activity level again.

Some key advantages of the present invention are: the present invention does not require any wiring or connections to the vehicle's engine, transmission, alternator, or any other subsystem in the vehicle. The mounting position does not have to be a particular orientation. The present invention does not require the use of a microphone. Prior art is aimed at compensating for ambient noise to give the user a consistent relative volume level from his audio system. The present invention does this also, plus the present invention can adjust the volume to different relative volume levels desired during different activity events.

Many examples of prior art exist which require a connection to a vehicle subsystem. Connections to a vehicle's subsystem can be inconvenient to install and often require special knowledge to install properly. Prior art which does not require a connection to a vehicle subsystem instead uses one or more microphones. Use of microphones to attempt to detect the level of ambient noise is unreliable and such a device can be complex to install when using more than one microphone.

The present invention can be practiced in a number of different embodiments and used on a number of different types of vehicles. Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

I claim:

1. A method for controlling the volume level of an audio system in a vehicle comprising:
determining the amount of tilt of said vehicle when said vehicle is at rest;
detecting a change in the amount of tilt of said vehicle; and
changing the volume of said audio system according to said change in the amount of tilt.

2. The method of claim 1 wherein determining the amount of tilt is by means of an acceleration sensor and filter.

3. The method of claim 1 further comprising:
detecting the amount of acceleration of said vehicle along one or more axes,
wherein said changing the volume is also according to said amount of acceleration.

4. The method of claim 3 wherein determining the amount of tilt is by means of an acceleration sensor and filter.

5. The method of claim 3 further comprising:
receiving volume adjustment commands from a user input,
wherein said changing the volume is also according to said volume adjustment commands.

6. The method of claim 5 wherein determining the amount of tilt is by means of an acceleration sensor and filter.

7. An autonomous volume control apparatus comprising:
a tilt detector for detecting the amount of tilt of said apparatus;
a volume control interface; and
a decision processor,
whereby the decision processor adjusts the volume of said audio system via said volume control interface according to changes in said amount of tilt.

8. The apparatus of claim 7 wherein said tilt detector comprises an acceleration sensor and filter.

9. The apparatus of claim 7, further comprising:
one or more acceleration sensors for measuring acceleration of said apparatus along one or more axes,
whereby the decision processor adjusts the volume of said audio system via said volume control interface also according to the amount of acceleration.

10. The apparatus of claim 9 wherein said tilt detector comprises an acceleration sensor and filter.

11. The apparatus of claim 9, further comprising:
a user interface for receiving volume adjustment commands, whereby the decision processor adjusts the volume of said audio system via said volume control interface also according to said volume adjustment commands.

12. The apparatus of claim 11 wherein said tilt detector comprises an acceleration sensor and filter.
